(19) United States
(12) Patent Application Publication
(10) Pub. No.: US 2002/0064962 A1
(43) Pub. Date: May 30, 2002

(54) Method for improving electrical characteristics of oxide film grown on gallium arsenide by plasma treatment

(76) Inventors: Yeong-Her Wang, Tainan (TW); Mau-Phon Hong, Tainan (TW); Yao-Jun Zhang, Changhua (TW)

Correspondence Address: Skjerven, Morrill,, MacPherson LLP, Suite 700, 25 Metro Drive, San Jose, CA, 95110, US

(21) Appl. No.: 09/833,721

(22) Filed: Apr. 11, 2001

(30) Foreign Application Priority Data
Nov. 28, 2000 (TW) 89125260

(51) Int. Cl. H01L 21/302; H01L 21/461

(52) U.S. Cl. 438/712

(57) ABSTRACT

A method is provided for improving electrical characteristics of an oxide film grown on a III-V substrate by plasma treatment and being used in fabricating semiconductor, integrated circuit, and photoelectric elements. The method includes steps of a) providing the III-V substrate, b) growing the oxide film on said III-V substrate, and c) placing the oxide grown on the III-V substrate in a plasma system.

### FIELD OF THE INVENTION

The present invention relates to a method for improving electrical characteristics of an oxide, and more particularly to a method for improving electrical characteristics of an oxide film grown on gallium arsenide (GaAs) by plasma treatment.

### BACKGROUND OF THE INVENTION

GaAs-based transistors and circuits are widely used. GaAs offers several advantages such as higher speed, packing density, and wider band gap, especially for processing the metal semiconductor field-effect transistor (MESFET). But, oxidation of GaAs is not processed easily and the available property is not good enough. Furthermore, the GaAs substrate is not stable at the high temperature ( above 650.degree.C.), so the GaAs substrate can not be processed at high temperature as silicon.

In the prior art, a liquid phase chemical-assisted oxidation is utilized to grow an oxide film on GaAs at near room temperature. The oxide film provided by the liquid phase chemical-assisted oxidation is homogenous, smooth, electric insulated, and chemical stoichiometric. However, the properties of leakage current and breakdown voltage are still need to be improved.

There are some conventional methods for improving properties of an oxide film. One method is to treat the surface of GaAs by hydrogen or nitrogen plasma. The other is used in the surface passivation of GaAs by liquid sulphur treatment. However, the prior art is used for treating the surface of GaAs to improve the properties of the oxide subsequently grown thereon.

In order to overcome foresaid drawbacks, the present invention provides a method for improving the electrical characteristics of the oxide film, which is grown on the gallium arsenide wafer by liquid phase chemical-enhanced oxidation, by plasma treatment.

### SUMMARY OF THE INVENTION

It is therefore an object of the present invention to provide a method for improving electrical characteristics of an oxide film grown on a III-V substrate by plasma treatment and being used in fabricating semiconductor, integrated circuit, and photoelectric elements.

In accordance with the present invention, the method includes steps of a) providing the III-V substrate, b) growing the oxide film on the III-V substrate, and c) placing the oxide film grown on the III-V substrate in a plasma system.

The method further includes a step of adjusting parameters of the plasma system to treat the oxide film for improving the electrical characteristics of the oxide film.

In accordance with the present invention, the parameters of the plasma system includes vacuity of the plasma system, pressure and current produced by the plasma, radio frequency, and voltage.

Preferably, the III-V substrate is a compound constituting a IIIA element and a VA element, wherein the IIIA element is selected from a group consisting of aluminum, gallium, indium and thallium, and the VA-element is arsenic.

Preferably, the III-V substrate is a gallium arsenide wafer.

Preferably, the oxide film is grown in a growth solution by liquid phase chemical-assisted oxidation.

Preferably, the growth solution is prepared by mixing a 10% nitric acid and a 10% ammonia water to adjust the pH to maintain at about 5.5.

Furthermore, the plasma system includes a reactive ion etching machine, a sputtering machine, and reactive gas. Preferably, the reactive gas is one of nitrogen and hydrogen or a mixture of nitrogen and hydrogen.

It is another object of the present invention to provide a method for providing a III-V substrate having an oxide film thereon for fabricating semiconductors, integrated circuits, and photoelectric elements, wherein an oxide in the oxide film is reduced by plasma treatment to improve electrical characteristics of the oxide film.

In accordance with the present invention, the III-V substrate is a compound constituting a IIIA element and a VA element, wherein the IIIA element is selected from a group consisting of aluminum, gallium, indium and thallium, and the VA element is arsenic.

Preferably, the III-V substrate is a gallium arsenide wafer.

Preferably, the oxide film is grown in a growth solution by liquid phase chemical-assisted oxidation. The growth solution is prepared by mixing a 10% nitric acid and a 10% ammonia water to adjust the pH to maintain at about 5.5.

Furthermore, the plasma treatment is utilized with a plasma system comprising a reactive ion etching machine, a sputtering machine, and a reactive gas.

Preferably, the reactive gas is one of nitrogen and hydrogen, or a mixture of nitrogen and hydrogen.

The present invention may best be understood through the following description with reference to the accompanying drawings, in which:

### BRIEF DESCRIPTION OF THE DRAWING

FIG. 1 is a diagram showing the relationship between current density and voltage of metal-insulator-semiconductor diode according to the present invention, wherein the thickness of the oxide film is 800 angstrom;

FIG. 2 is a diagram showing the relationship between current density and voltage of metal-insulator-semiconductor diode according to the present invention, wherein the thickness of the oxide film is 500 angstrom;

FIG. 3 (a) is a diagram showing the arsenic content of the oxide film analyzed by secondary ion mass spectroscopy;

FIG. 3 (b) is an amplified diagram of FIG. 3 (A); and

FIG. 4 is a diagram showing the arsenic bonding of the oxide film analyzed by X-ray photoelectron spectrum.

### DETAILED DESCRIPTION OF THE PREFERRED EMBODIMENTS

The structure of the GaAs wafer used in the preferred embodiment of the present invention has three layers. The bottom layer is an N+ GaAs substrate. The middle layer is an n type GaAs semiconductor doping with silicon. The doping concentration of the middle layer is 5×10¹⁸ cm⁻³, and the thickness of the middle layer is about 3000 angstrom. The top layer is an n type GaAs semiconductor doping with silicon. The doping concentration of the top layer is 2×10¹⁶ cm⁻³, and the thickness of the middle layer is about 8000 angstrom.

The GaAs wafer is cleaned with acetone in the supersonicator. The GaAs wafer is washed on a hot plate and then rinsed and washed with methanol.

Then, the oxide layer is grown on the GaAs wafer by the liquid phase chemical-assisted oxidation method. A growth solution is prepared by mixing a diluted 10% nitric acid and a 10% diluted ammonia water to adjust the pH value to maintain at about 5.5. The temperature of the growth solution is maintained at about 50° C. When the pH value of the growth solution is adjusted about to 4.88, the GaAs wafer is placed into the growth solution to grow the oxide film on the GaAs wafer. Certainly, the growing rate of the oxide film could be increased by agitation.

Subsequently, the GaAs wafer having the oxide film thereon is put in a reactive ion etching (RIE) system. For activating the reactive ion etching system, the vacuity of the system is maintained at 10⁻⁶ Torr, and then the flow rate of the gas is controlled with nitrogen. In the meanwhile, the pressure of the system is controlled at the range from 20 to 100 mTorr by a continuous pressure controller. When the pressure and the gas flow rate of the system are stable, the power of radio frequency (RF) is set. For instant, the power of radio frequency is 30 W, 50 W, or 70 W. Subsequently, the GaAs wafer having the oxide film thereon is treated by the nitrogen plasma for 10 to 20 minutes.

Although the bottom layer of the GaAs wafer is placed in the bottom of the container and could not be in contact with the growth solution easily, the coating of photoresist on the oxide film is still formed to protect the oxide film. Then, the GaAs wafer is immersed in a hydrofluoric acid solution diluted with 10 volume of deionized water to remove the oxide grown on the bottom layer of the GaAs wafer for forming an ohm contact of the bottom layer of the GaAs wafer. Then, the photoresist film is stripped with acetone.

Because of the bottom layer of the GaAs wafer having high doping concentration, the bottom layer of the GaAs wafer is plated with Au—Ge—Ni, and then the GaAs wafer is placed on the hot plate. The ohm contact is formed under nitrogen at 400.degree.C. for 25 seconds.

Subsequently, the coating of photoresist is formed on the top layer of the GaAs wafer, the GaAs wafer is baked for 20 minutes, and then the GaAs wafer is performed by exposure and development. A metal-insulator-semiconductor diode having high conductivity is formed.

For illustrating the improved characteristics of the oxide film grown on the GaAs wafer according to the preferred embodiment of the present invention, it is described in detail with reference to the drawings and illustrated as follows:

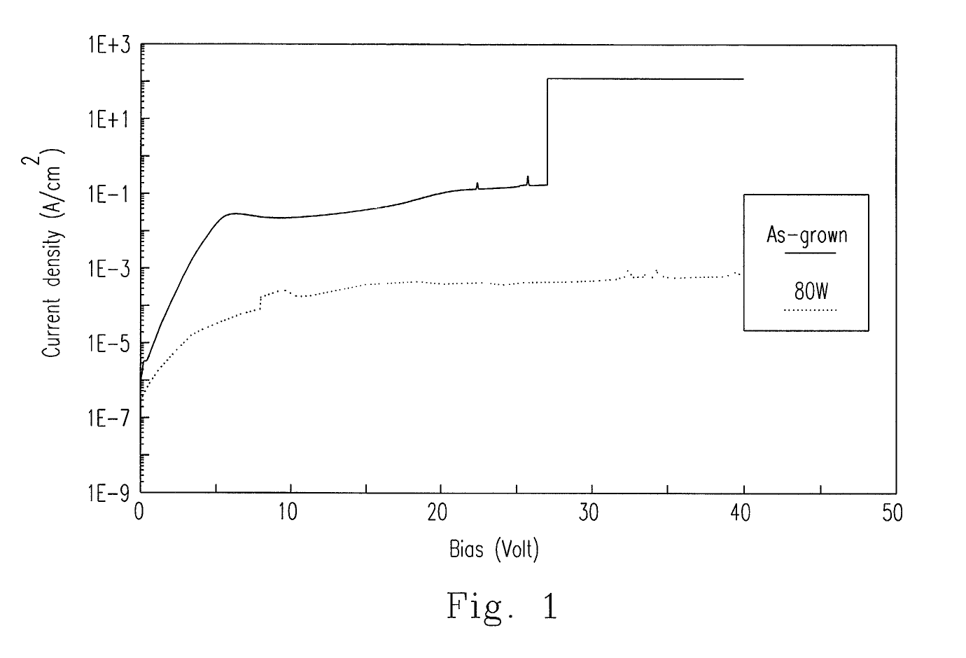

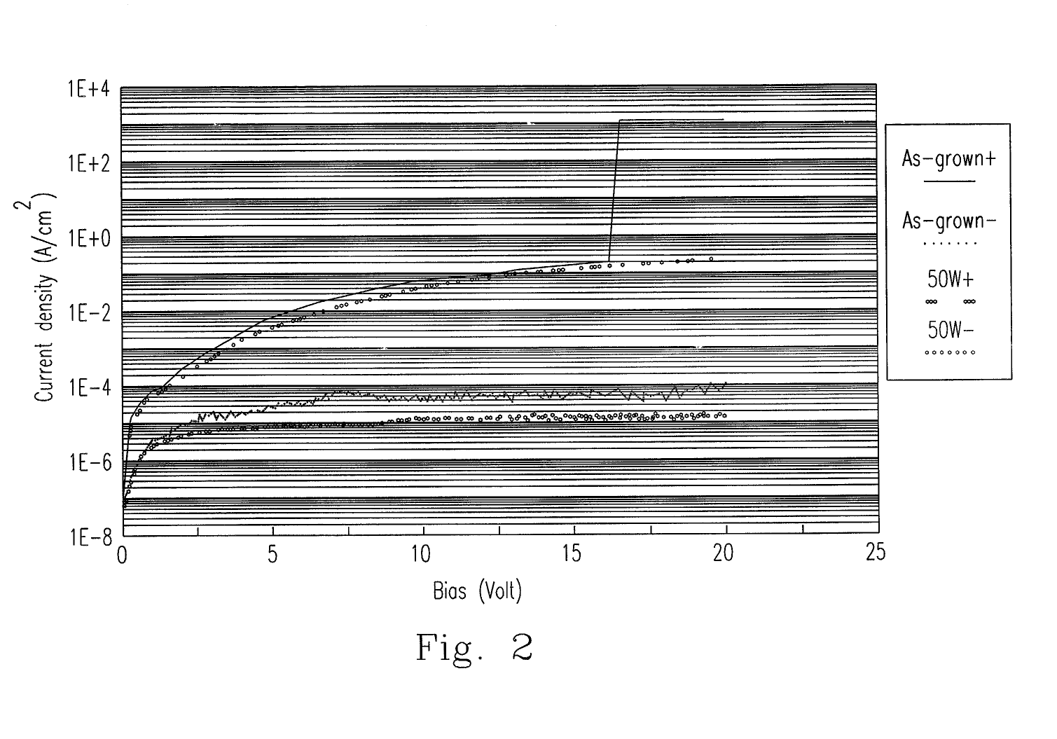

The GaAs wafer is tested by HP4156A, which is a DC parametric analyzer. The test results show that the leakage current and the breakdown voltage of the GaAs wafer treated by nitrogen plasma are much more improved than the GaAs wafer non-treated by nitrogen plasma. As shown in FIG. 1, in the condition that the thickness of the oxide film is 800 angstrom(pressure: 80 mTorr, flow rate: 10 sccm for 20 minutes), the leakage current density of the GaAs wafer treated by 80 W nitrogen plasma is decreased to 1/100. The breakdown voltage of the GaAs wafer treated by 80 W nitrogen plasma is much higher than 5 MV/cm. As shown in FIG. 2, in the condition that the thickness of the oxide film is 500 angstrom (pressure: 50 mTorr, flow rate: 10 sccm for 10 minutes) and plus bias voltage is applied, the breakdown voltage of the GaAs wafer treated by 50 W nitrogen plasma is much higher than 4 MV/cm. When the bias is −20 V, the leakage current of the GaAs wafer is decreased to 1×10⁻⁴ A/cm². Because the GaAs wafer is n type, the major carriers are electrons. The leakage current of the GaAs wafer at plus bias is higher than the leakage current of the GaAs wafer at minus bias.

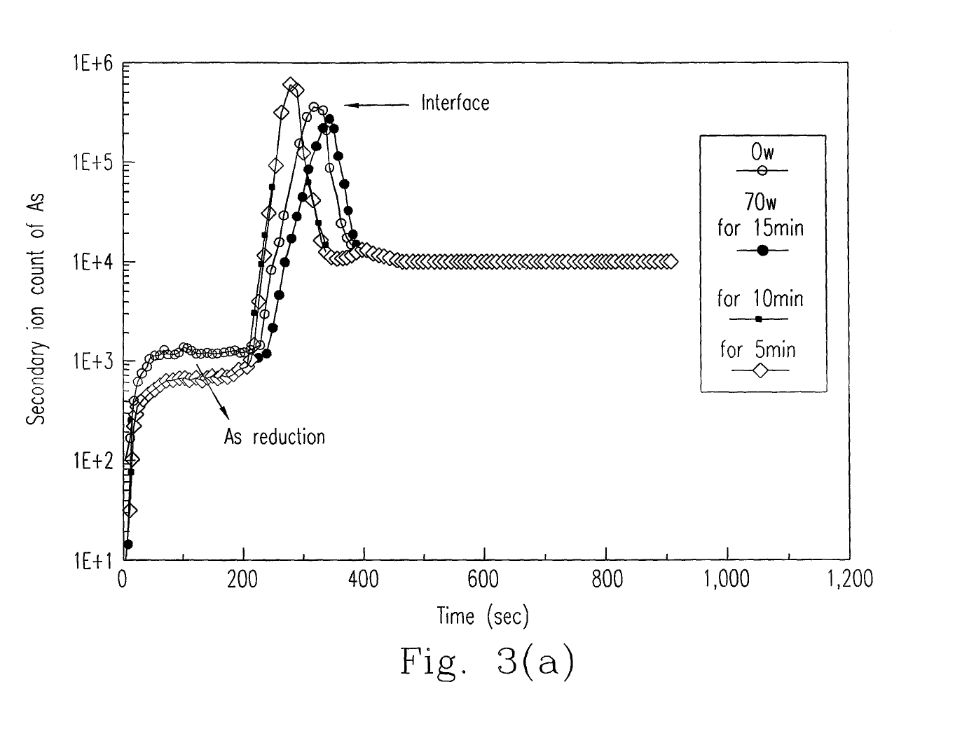

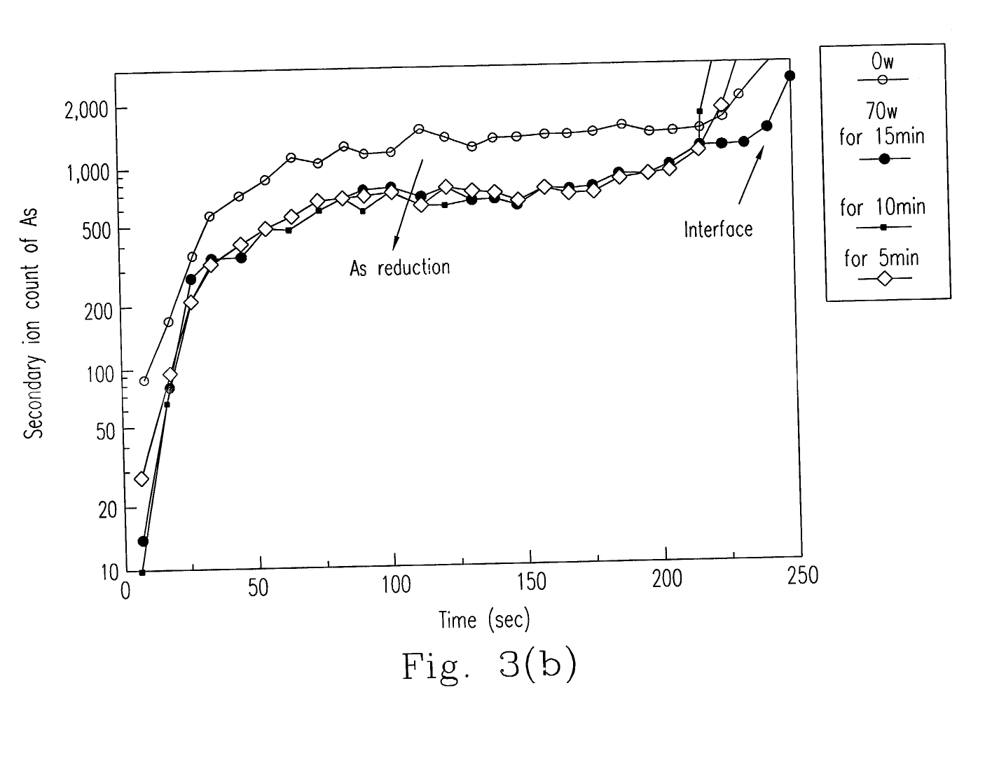

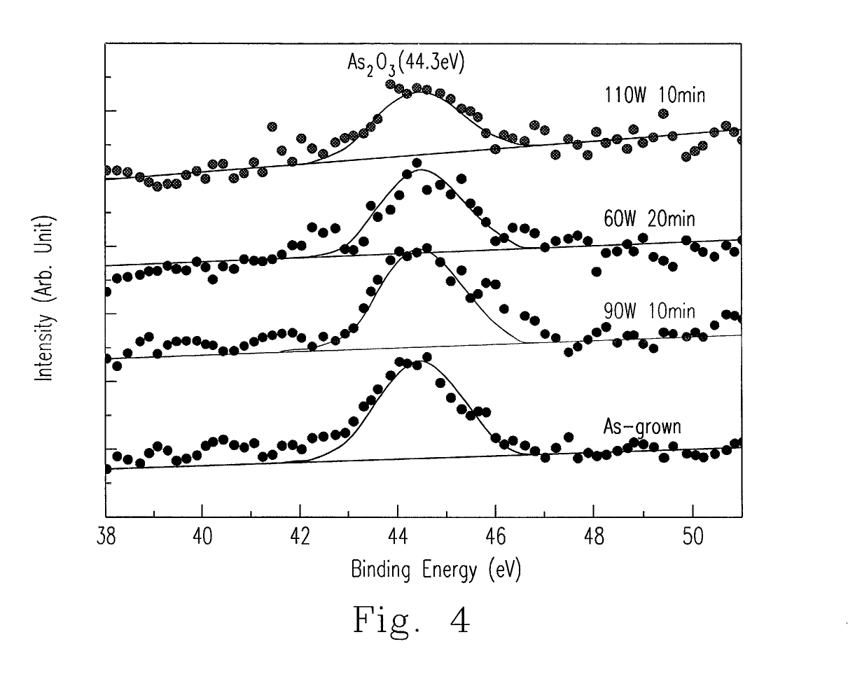

Referring to FIGS. 3 (a), 3 (b) and 4, in order to explore the mechanism in the oxide film of the GaAs wafer, the oxide film is analyzed by secondary ion mass spectroscopy (SIMS) and X-ray photoelectron spectrum (XPS). The arsenic content of the oxide film treated by nitrogen plasma is corresponding to the half arsenic content of the oxide film non-treated by nitrogen plasma. However, the arsenic content of GaAs from the GaAs wafer treated by nitrogen plasma is similar to the arsenic content of the GaAs wafer non-treated by nitrogen plasma (not shown).

As shown in FIG. 4, when the GaAs wafer is treated by nitrogen plasma, the signal of As₂O₃ is lower. The results analyzed from SIMS test and XPS test are consistent.

The method according to the present invention could be used for improving leakage current and breakdown voltage of oxide film. Certainly, the method according to the present invention could be used in the manufacturing process of the metal-oxide semiconductor to improve the characteristics of the elements.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A method for improving electrical characteristics of an oxide film grown on a III-V substrate by plasma treatment and being used in fabricating semiconductor, integrated circuit, and photoelectric elements, comprising steps of:
a) providing said III-V substrate;
b) growing said oxide film on said III-V substrate; and
c) placing said oxide grown on said III-V substrate in a plasma system.

2. The method according to claim 1 further comprising a step of adjusting parameters of said plasma system to treat said oxide film for improving said electrical characteristics of said oxide film.

3. The method according to claim 2, wherein said parameters of said plasma system includes vacuity of said plasma system, pressure and current produced by said plasma, radio frequency, and voltage.

4. The method according to claim 1, wherein said III-V substrate is a compound constituting a IIIA element and a VA element, wherein said IIIA element is selected from a group consisting of aluminum, gallium, indium and thallium, and said VA element is arsenic.

5. The method according to claim 4, wherein said III-V substrate is a gallium arsenide wafer.

6. The method according to claim 1, wherein said oxide film is grown in a growth solution by liquid phase chemical-assisted oxidation.

7. The method according to claim 6, wherein said growth solution is prepared by mixing a 10% nitric acid and a 10% ammonia water to adjust pH to maintain at about 5.5.

8. The method according to claim 1, wherein said plasma system comprises a reactive ion etching machine and a sputtering machine.

9. The method according to claim 1, wherein said plasma system comprises a reactive gas.

10. The method according to claim 9, wherein said reactive gas is one of nitrogen and hydrogen.

11. The method according to claim 9, wherein said reactive gas is a mixture of nitrogen and hydrogen.

12. A method for providing a III-V substrate having an oxide film thereon for fabricating semiconductors, integrated circuits, and photoelectric elements, wherein an oxide in said oxide film is reduced by plasma treatment to improve electrical characteristics of said oxide film.

13. The method according to claim 12, wherein said III-V substrate is a compound constituting a IIIA element and a VA element, wherein said IIIA element is selected from a group consisting of aluminum, gallium, indium and thallium, and said VA element is arsenic.

14. The method according to claim 13, wherein said III-V substrate is a gallium arsenide wafer.

15. The method according to claim 12, wherein said oxide film is grown in a growth solution by liquid phase chemical-assisted oxidation.

16. The method according to claim 15, wherein said growth solution is prepared by mixing a 10% nitric acid and a 10% ammonia water to adjust pH to maintain at about 5.5.

17. The method according to claim 12, wherein said plasma treatment is utilized with a plasma system comprising a reactive ion etching machine and a sputtering machine.

18. The method according to claim 17, wherein said plasma system comprises a reactive gas.

19. The method according to claim 18, wherein said reactive gas is one of nitrogen and hydrogen.

20. The method according to claim 18, wherein said reactive gas is a mixture of nitrogen and hydrogen.
